(19) United States
(12) Patent Application Publication
(10) Pub. No.: US 2026/0096155 A1
(43) Pub. Date: Apr. 2, 2026

(54) SEMICONDUCTOR DEVICE INCLUDING ANTIFERROMAGNETIC LAYER AND DATA STORAGE SYSTEMS INCLUDING THE SAME

(71) Applicant: SAMSUNG ELECTRONICS CO., LTD., Suwon-si (KR)

(72) Inventors: Sungwon KIM, Suwon-si (KR); Hyoungsub KIM, Suwon-si (KR); Hyungjoon KIM, Suwon-si (KR); Jehoon LEE, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 19/341,901

(22) Filed: Sep. 26, 2025

(30) Foreign Application Priority Data
Sep. 30, 2024 (KR) 10-2024-0132857
Jan. 23, 2025 (KR) 10-2025-0010189

(51) Int. Cl. H10D 30/69; H10B 43/27; H10D 64/68

(52) U.S. Cl. CPC H10D 30/69; H10B 43/27; H10D 64/685

(57) ABSTRACT

Provided is a semiconductor device including: a source structure; a stack structure including interlayer insulating layers and gate electrodes stacked in a first direction perpendicular to an upper surface of the source structure; and a channel structure penetrating the stack structure and the source structure in the first direction, the channel structure including a channel layer, a data storage layer on the channel layer, and a blocking structure between the data storage layer and the gate electrodes, wherein the blocking structure including an antiferroelectric layer including a first crystal structure.

### CROSS-REFERENCE TO RELATED APPLICATIONS

This application is based on and claims priority to Korean Patent Application No. 10-2025-0010189, filed on Jan. 23, 2025 in the Korean Intellectual Property Office, and Korean Patent Application No. 10-2024-0132857 filed on Sep. 30, 2024 in the Korean Intellectual Property Office, the disclosures of which are incorporated herein by reference in their entirety.

### BACKGROUND

### 1. Field

The present disclosure relates to a semiconductor device, a method of manufacturing the same, and a data storage system including the semiconductor device.

### 2. Description of Related Art

In an electronic system requiring data storage, a semiconductor device which may store a large amount of data may be necessary. Accordingly, a method for increasing data storage capacity of a semiconductor device has been studied. For example, as one of method of increasing data storage capacity of a semiconductor device, a semiconductor device including memory cells arranged three-dimensionally, instead of memory cells arranged two-dimensionally, has been suggested.

### SUMMARY

Provided is a semiconductor device in which a charge trapping layer may be included as a data storage structure in a channel structure, and an antiferroelectric layer having antiferroelectric properties to boost the charge trapping layer may be further included. Accordingly, during a program operation, high saturation polarization may be formed by a strong electric field, such that electrons may gather in the charge trapping layer, and when the electric field is removed after a program operation, the layer may function as a general insulating layer due to characteristics of antiferroelectric properties in which spontaneous polarization is eliminated, such that electrons stored in the charge trapping layer may not be affected without a back gate voltage.

Further provided is a data storage system including the semiconductor device.

Further provided is a method of manufacturing the semiconductor device.

According to an aspect of the disclosure, a semiconductor device includes: a source structure; a stack structure including interlayer insulating layers and gate electrodes stacked in a first direction perpendicular to an upper surface of the source structure; and a channel structure penetrating the stack structure and the source structure in the first direction, the channel structure including a channel layer, a data storage layer on the channel layer, and a blocking structure between the data storage layer and the gate electrodes, wherein the blocking structure including an antiferroelectric layer including a first crystal structure.

According to an aspect of the disclosure, a semiconductor device includes: a source structure; a stack structure including interlayer insulating layers and gate electrodes stacked in a first direction perpendicular to an upper surface of the source structure, the stack structure including a channel hole penetrating the interlayer insulating layers and the gate electrodes in the first direction; a filling insulating layer in a center of the channel hole; a channel layer on an external side surface of the filling insulating layer; a tunneling layer on an external side surface of the channel layer; a charge trapping layer on the tunneling layer; an antiferroelectric layer on the charge trapping layer, the antiferroelectric layer configured to have spontaneous polarization when a voltage is applied; and a crystal seed layer on one side surface of the antiferroelectric layer, wherein the antiferroelectric layer has a tetragonal crystal structure.

According to an aspect of the disclosure, a data storage system includes: a semiconductor device including an input/output pad; and a controller connected to the semiconductor device through the input/output pad, wherein the controller is configured to control the semiconductor device, wherein the semiconductor device includes: a source structure; a stack structure including interlayer insulating layers and gate electrodes stacked in a first direction perpendicular to an upper surface of the source structure, the stack structure including a channel hole penetrating the interlayer insulating layers and the gate electrodes in the first direction; a filling insulating layer in a center of the channel hole; a channel layer on an external side surface of the filling insulating layer; a tunneling layer on an external side surface of the channel layer; a charge trapping layer on the tunneling layer; an antiferroelectric layer on the charge trapping layer, the antiferroelectric layer configured to have spontaneous polarization when a voltage is applied; and a crystal seed layer on one side surface of the antiferroelectric layer, and wherein the antiferroelectric layer has a tetragonal crystal structure.

A method of manufacturing a semiconductor device includes: forming an element isolation layer, a circuit gate dielectric layer, and a circuit gate electrode layer in order on a first substrate; forming spacer layers sidewalls of the circuit gate dielectric layer and the circuit gate electrode layer; forming source/drain regions on the first substrate by introducing impurities on both sides of the circuit gate electrode layer; forming lower contact plugs of a lower interconnection structure by forming a portion of a lower capping layer, etching and removing a portion thereof, and filling a conductive material; forming a second substrate on the lower capping layer; forming a horizontal sacrificial structure on the second substrate; forming a substrate insulating layer; forming a lower mold structure by alternately stacking sacrificial insulating layers and interlayer insulating layers on the second horizontal conductive layer; replacing a portion of the sacrificial insulating layers with gate electrodes; forming vertical sacrificial structures by anisotropically etching the lower mold structure using a mask layer; forming first openings by removing the vertical sacrificial structures; consecutively forming, in the first openings, preliminary antiferroelectric layers, crystal seed layers, and first dielectric layers; forming a channel structure; and crystallizing the antiferromagnetic layers via an annealing process.

### BRIEF DESCRIPTION OF THE DRAWINGS

The above and other aspects and features of the present disclosure will be more clearly understood from the following detailed description, taken in combination with the accompanying drawings, in which:

FIG. 1 is a cross-sectional diagram illustrating a transistor to which an antiferroelectric layer is applied according to one or more embodiments of the present disclosure;

FIG. 2 is a plan diagram and an enlarged diagram illustrating a semiconductor device according to one or more embodiments of the present disclosure;

FIG. 3 is a cross-sectional diagram illustrating a semiconductor device according to one or more embodiments of the present disclosure;

FIG. 4 is an enlarged cross-sectional diagram illustrating a portion of a semiconductor device according to one or more embodiments of the present disclosure;

FIG. 5 is a graph indicating characteristics of an antiferroelectric layer according to one or more embodiments of the present disclosure;

FIG. 6A and FIG. 6B are diagrams illustrating a program operation of a semiconductor device and a state after the program operation according to one or more embodiments of the present disclosure;

FIG. 7A and FIG. 7B are graphs indicating characteristics of a dielectric structure of a semiconductor device according to one or more embodiments of the present disclosure;

FIG. 8, FIG. 9, FIG. 10, and FIG. 11 are enlarged cross-sectional diagrams illustrating a portion of a modified example;

FIG. 12 is a cross-sectional diagram illustrating a semiconductor device according to one or more embodiments of the present disclosure;

FIG. 13A, FIG. 13B, FIG. 13C, FIG. 13D, FIG. 13E, and FIG. 13F are diagrams illustrating a method of manufacturing a semiconductor device according to one or more embodiments of the present disclosure;

FIG. 14 is a diagram illustrating a data storage system including a semiconductor device one or more embodiments of the present disclosure; and

FIG. 15 is a perspective diagram illustrating a data storage system including a semiconductor device one or more embodiments of the present disclosure.

### DETAILED DESCRIPTION

Hereinafter, embodiments of the present disclosure will be described as follows with reference to the accompanying drawings.

Hereinafter, the terms such as “upper,” “intermediate,” and “lower” may be replaced with other terms, such as “first,” “second,” and “third,” to describe components in example embodiments. The terms such as “first,” “second,” and “third” may be used to describe various components, but the components are not limited to the terms, and a “first component” may be denoted as a “second component.”

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

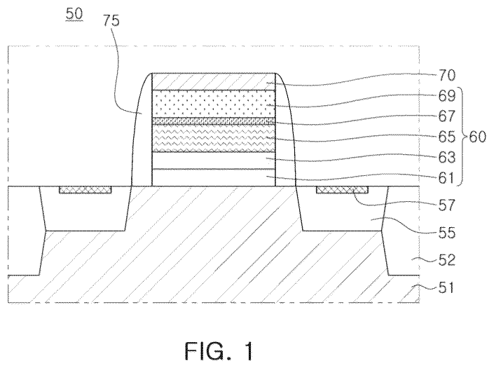

FIG. 1 is a cross-sectional diagram illustrating a planar transistor to which an antiferroelectric layer is applied according to one or more embodiments.

Referring to FIG. 1, in one or more embodiments, a transistor may be included as a memory element 50.

The memory element 50 may include a gate structure and source/drain impurity regions 55 disposed on both sides of the gate structure disposed on a substrate 51.

The substrate 51 may include a semiconductor material, such as a group IV semiconductor, a group III-V compound semiconductor, or a group II-VI compound semiconductor. The substrate 51 may be provided as a bulk wafer or an epitaxial layer.

The memory element 50 may be an NMOS transistor or a PMOS transistor, depending on a conductivity type of the substrate 51 or a well region.

When the substrate 51 or the well region is doped with impurities of a first conductivity type, the source drain impurity regions 55 may include an impurity region of a second conductivity type different from the first conductivity type. For example, the source drain impurity regions 55 may include a region doped with N-type impurities. A high-concentration doping region 57 may be further disposed in a portion of an upper portion of the impurity regions 55.

The gate structure may include a gate dielectric structure 60, a gate electrode 70, and a gate spacer 75 covering sidewalls of the gate dielectric structure 60 and the gate electrode 70.

The gate dielectric structure 60 may include a multilayer stack structure.

The gate dielectric structure 60 includes a tunneling layer 61 in contact with the substrate 51, and the tunneling layer 61 may be a silicon oxide film.

A silicon nitride film may be included on the tunneling layer 61 as a charge trapping layer 63. The silicon nitride film may capture electrons injected from a channel, that is, the substrate 51 in a lower portion of the tunneling layer 61, and accordingly, the silicon nitride film may control a threshold voltage of the channel.

A first blocking layer 65 may be included on the charge trapping layer 63 in the gate dielectric structure 60. The first blocking layer 65 may include a high-κ material. The high-κ material may indicate a dielectric material having a higher dielectric constant than that of a silicon oxide film (SiO₂). The high-κ material may be, for example, one of aluminum oxide (Al₂O₃,), tantalum oxide (Ta₂O₃), and titanium oxide (TiO₂).

An antiferroelectric layer 69 may be included on the first blocking layer 65 in the gate dielectric structure 60.

The antiferroelectric layer 69 may include a material having antiferroelectric properties, and may include hafnium-zirconium oxide (HZO). In this case, the hafnium-zirconium oxide may have a tetragonal crystal structure and may thus have antiferroelectric properties.

The antiferroelectric layer 69 may have a high saturation polarization when an electric field is formed, and may provide a stronger attractive force or repulsive force to the charge trapping layer 63, and accordingly, electrons may be smoothly injected from the channel to the charge trapping layer 63.

The antiferroelectric layer 69 may function as a general insulating layer when an electric field is removed, as the spontaneous polarization disappears due to the antiferroelectric properties. Accordingly, the influence of a ferroelectric material due to residual spontaneous polarization on neighboring memory cells may be reduced, and leakage current may be reduced. Also, by boosting the charge trapping layer 63 using antiferroelectric properties of the antiferroelectric layer 69, memory efficiency may improve, and a memory window may be expended.

The antiferroelectric layer 69 may be most smoothly formed when hafnium-zirconium oxide (HZO) has a tetragonal crystal structure. Hafnium-zirconium oxide (HZO) may naturally have a mostly cubic crystal structure, and when having a cubic crystal structure, hafnium-zirconium oxide (HZO) may have ferroelectric properties rather than antiferroelectric properties. Accordingly, to ensure antiferroelectric properties of the antiferroelectric layer 69, a crystal seed layer 67 may be further included on an interfacial surface of the antiferroelectric layer 69.

The crystal seed layer 67 may function as a crystal inducing layer for crystallizing the antiferroelectric layer 69 to have a tetragonal crystal structure, and may include a material such as yttrium oxide (Y₂O₃). In this case, the crystal seed layer 67 may be a thin layer for inducing a crystal structure of the antiferroelectric layer 69, and may have a thickness less than that of the antiferroelectric layer 69.

A gate electrode 70 may be disposed on the gate dielectric structure 60. The gate electrode 70 may include a conductive material such as a metal layer, a polysilicon (poly-Si) layer, or a metal nitride. For example, the gate electrode 70 may include titanium nitride (TiN) or TSN (Ti—Si—N), tungsten (W), or the like.

The gate spacer 75 may be provided as a pair of spacers on sidewalls of the gate structure. The gate spacer 75 may include an oxide film, a nitride film, an oxide nitride film, or a combination thereof.

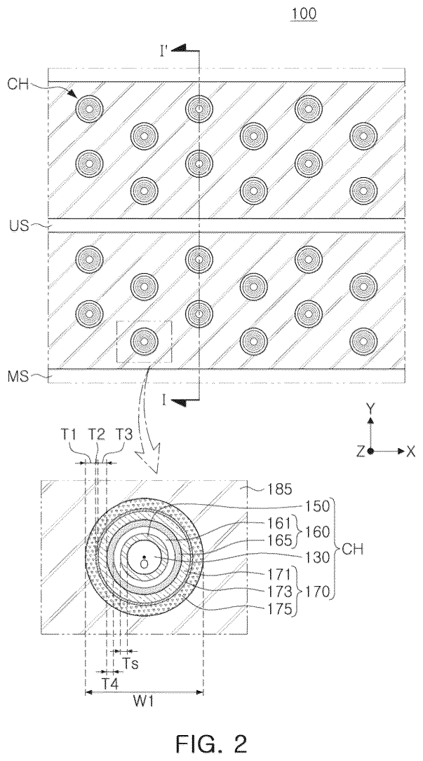

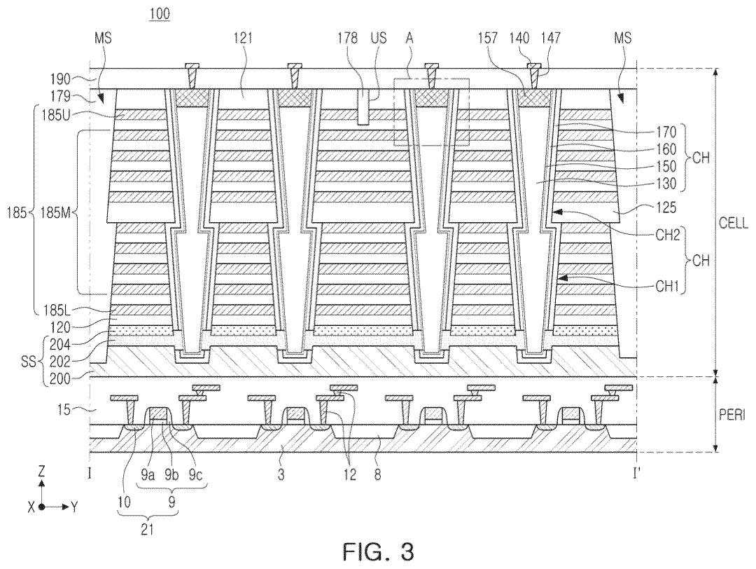

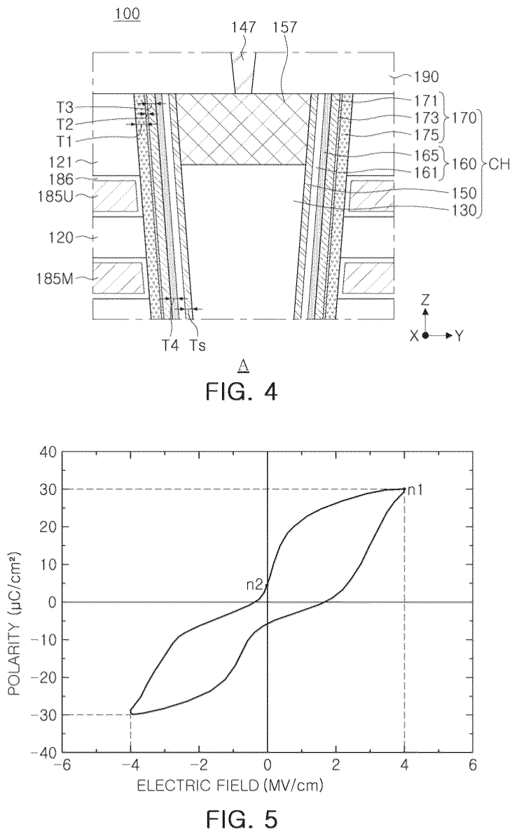

Hereinafter, referring to FIG. 2, FIG. 3, and FIG. 4, a semiconductor device in which the memory element in FIG. 1 is applied as a three-dimensional memory element will be described.

FIG. 2 is a plan diagram and an enlarged diagram illustrating a semiconductor device according to example embodiments, and FIG. 3 is a cross-sectional diagram illustrating a semiconductor device according to example embodiments, illustrating a cross-sectional surface taken along line I-I′ in FIG. 2. FIG. 4 is an enlarged cross-sectional diagram illustrating a portion of a semiconductor device according to one or more embodiments, illustrating region “A” in FIG. 3.

Referring to FIG. 2, FIG. 3, and FIG. 4, a semiconductor device 100 according to one or more embodiments may include a first region CELL and a second region PERI. The first region CELL may vertically overlap the second region PERI.

In one or more embodiments, the first region CELL may be a memory region in which memory cells arranged three-dimensionally are disposed, and the second region PERI may be a peripheral circuit region.

In one or more embodiments, the first region CELL may be referred to as a memory chip structure or a first chip structure, and the second region PERI may be referred to as a peripheral circuit structure or a second chip structure.

The second region PERI may include a first substrate 3, circuit elements 21 on the first substrate 3, a lower interconnection structure 12, and a lower capping layer 15.

The first substrate 3 may include a semiconductor material, for example, a group IV semiconductor, a group III-V compound semiconductor, or a group II-VI compound semiconductor. The first substrate 3 may be provided as a bulk wafer or an epitaxial layer. An active region may be defined by element isolation layers on the first substrate 3. Source/drain regions 10 including impurities may be disposed in a portion of the active region.

Circuit elements 21 may include a transistor. Each of the circuit elements 21 may include a circuit gate dielectric layer 9b, a circuit gate electrode 9a, and a source/drain region 10. Source/drain regions 10 including impurities may be disposed in the first substrate 3 on both sides of the circuit gate electrode 9a. Spacer layers may be disposed on both sides of the circuit gate electrode 9a. The circuit gate dielectric layer 9b may include silicon oxide, silicon nitride, or a high-κ material. The circuit gate electrode 9a may include at least one of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). The circuit gate electrode 9a may include a semiconductor layer, for example, a doped polycrystalline silicon layer. According to one or more embodiments, the circuit gate electrode 9a may include two or more multilayers.

The lower interconnection structure 12 may be electrically connected to the circuit gate electrodes 9a and the source/drain regions 10 of the circuit elements 21. The lower interconnection structure 12 may include lower contact plugs having a cylindrical or conical shape and lower interconnection lines having at least one region having a line shape. A portion of the lower contact plugs may be connected to the source/drain regions 10, and the other portion of the lower contact plugs may be connected to the gate electrodes 9a. The lower contact plugs may electrically connect lower interconnection lines 12 disposed at different levels from an upper surface of the first substrate 3 to each other. The lower interconnection structure 12 may include a conductive material, for example, tungsten (W), copper (Cu), or aluminum (Al), and each of the elements may further include a diffusion barrier including at least one of titanium (Ti), titanium nitride (TiN), tantalum (Ta), tantalum nitride (TaN), or tungsten nitride (WN). According to example embodiments, the number of layers of lower contact plugs and lower interconnection lines included in the lower interconnection structure 12 and arrangement thereof may be varied.

The lower capping layer 15 may be disposed on the first substrate 3, and may cover the circuit elements 21 and the lower interconnection structure 12. The lower capping layer 15 may include a plurality of insulating layers. The lower capping layer 15 may include an insulating material, for example, silicon oxide, silicon nitride, silicon oxynitride, or silicon oxycarbide.

The first region CELL may include a source structure SS, gate electrodes 185 stacked on the source structure SS, interlayer insulating layers 120 alternately stacked with the gate electrodes 185, an isolation region MS penetrating a stack structure of the gate electrodes 185 and the interlayer insulating layers 120 and extending in one direction, a channel structure CH penetrating the stack structure and the source structure SS, an upper isolation region US penetrating a portion of the stack structure between the channel structures CH, plugs 147 on the channel structures CH, and an upper interconnection structure on the stack structure.

The channel structures CH may be disposed in the cell region, and contact plugs for electrically connecting the channel structures CH to the second region PERI may be disposed in an extended region adjacent to the cell region. In the extended region, the gate electrodes 185 may be regions extending by different lengths, but the present disclosure is not limited thereto. In FIG. 2, FIG. 3, and FIG. 4, only the cell region is illustrated.

The source structure SS may include a second substrate 200 and first and second horizontal conductive layers 202 and 204. The second substrate 200 may be a conductive plate layer and may have an upper surface extending in the X-direction and the Y-direction. The second substrate 200 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). The second substrate 200 may be provided as a bulk wafer, an epitaxial layer, an epitaxial layer, a silicon on insulator (SOI) layer, or a semiconductor on insulator (SeOI) layer.

The first and second horizontal conductive layers 202 and 204 may be stacked in order on an upper surface of the second substrate 200. The first and second horizontal conductive layers 202 and 204 may be source layers and may form a source structure SS together with the second substrate 200. The source structure SS may function as a source line of the semiconductor device 100. The first horizontal conductive layer 202 may be directly connected to the channel layer 150 around the channel layer 150.

The first and second horizontal conductive layers 202 and 204 may include a semiconductor material, for example, polycrystalline silicon. For example, the first horizontal conductive layer 202 may be doped with N-type impurities. The second horizontal conductive layer 204 may be a doped layer, or may be an intrinsic semiconductor layer including impurities diffused from the first horizontal conductive layer 202. However, the material of the second horizontal conductive layer 204 is not limited to a semiconductor material, and may be replaced with an insulating layer in example embodiments.

The stack structure may include interlayer insulating layers 120 and gate electrodes 185 alternately and repeatedly stacked in the Z-direction. The stack structure may vertically overlap the second region PERI, which may be a peripheral circuit structure.

The gate electrodes 185 may be vertically stacked and spaced apart from each other on the second substrate 200 and may form the stack structure. The gate electrodes 185 may be disposed between the second substrate 200 and the upper interconnection structure. The gate electrodes 185 may form an upper portion gate stack group on the lower gate stack group and the lower gate stack group. An intermediate interlayer insulating layer 125 disposed between the lower gate stack group and the upper gate stack group may have a relatively great thickness, but the present disclosure is not limited thereto.

The gate electrodes 185 may include electrodes forming a ground select transistor, memory cells, and a string select transistor in order from the second substrate 200. The number of gate electrodes 185 included in the memory cells may be determined depending on storage capacity of the semiconductor device 100. In one or more embodiments, each number of the gate electrodes 185 included in the string select transistor and the ground select transistor may be one, two, or more, and may have a structure the same as or different from the gate electrodes 185 of the memory cells.

The gate electrodes 185 may include lower gate electrodes 185L, intermediate gate electrodes 185M, and upper gate electrodes 185U.

The intermediate gate electrodes 185M may form wordlines of the memory cells, and the intermediate gate electrodes 185M may also be referred to as wordlines.

In an example, at least one of the lower gate electrodes 185L may be a lower select gate electrode, and at least one of the upper gate electrodes 185U may be an upper select gate electrode. For example, at least one of the lower gate electrodes 185L may be a gate electrode of a ground select transistor, and at least one of the upper gate electrodes 185U may be a gate electrode of a string select transistor. In an example, at least one of the lower gate electrodes 185L and the upper gate electrodes 185U may be an erase control gate electrode which may be used for an erase operation by generating a GIDL (gate induced drain leakage) current by a GIDL phenomenon in a NAND flash memory device.

The gate electrodes 185 may include a conductive material. For example, each of the gate electrodes 185 may be formed of polysilicon, W, Ru, Mo, Nb, Ni, Co, Ti, Ta, TiN, TaN, WN, NbN, TiAl, TiAlN, TiSi, TiSiN, TaSi, TaSiN, RuTiN, NiSi, CoSi or a combination thereof, but the present disclosure is not limited thereto. For example, each of the gate electrodes 185 may include a single layer or multiple layers of the materials mentioned above. A diffusion barrier 186 may be further disposed on a surface of the gate electrodes 185, for example, the diffusion barrier 186 may include tungsten nitride (WN), tantalum nitride (TaN), titanium nitride (TiN), or a combination thereof.

The interlayer insulating layers 120 may be disposed alternately with the gate electrodes 185. The interlayer insulating layers 120 may be spaced apart from each other in the direction (Z-direction) perpendicular to the upper surface of the source structure SS, similarly to the gate electrodes 185. The interlayer insulating layers 120 may include an insulating material such as silicon oxide. The interlayer insulating layer 120 disposed on an uppermost gate electrode 185U among the interlayer insulating layers 120 may be defined as an upper interlayer insulating layer 121. The upper interlayer insulating layer 121 and the intermediate interlayer insulating layer 125 may have a thickness greater than that of the other interlayer insulating layers 120.

The isolation regions MS may extend by penetrating the gate electrodes 185 in the Z-direction. The isolation regions MS may penetrate the gate electrodes 185 stacked on the second substrate 200 and may be connected to the second substrate 200. The isolation insulating layer 179 may be disposed in the isolation regions MS. The isolation region MS may have a shape having a width decreasing toward the second substrate 200 due to a high aspect ratio. The isolation region MS may extend in the X-direction and may isolate the gate electrodes 185 from each other in the Y-direction. According to one or more embodiments, a conductive layer may be further disposed in the isolation insulating layer 179 in the isolation regions MS. The isolation insulating layer 179 may include an insulating material, such as silicon oxide or silicon nitride, for example, silicon oxide, silicon nitride, or silicon oxynitride.

The upper isolation region US may extend in the X-direction between adjacent gate isolation regions MS in the Y-direction. The upper isolation region US may be disposed to penetrate some of the gate electrodes 185, including the upper gate electrodes 185U among the gate electrodes 185. The upper isolation region US may, for example, isolate the gate electrodes 185U from each other in the Y-direction as illustrated in FIG. 3. However, the number of gate electrodes 185 isolated by the upper isolation region US may be varied in one or more embodiments. The upper isolation region US may include an insulating material 178, for example, silicon oxide, silicon nitride, or silicon oxynitride.

The channel structures CH may be disposed to penetrate the stack structure and the source structure SS in order from the uppermost interlayer insulating layer 121. The channel structures CH may form a memory cell string and may be spaced apart from each other in rows and columns in the first region CELL. The channel structures CH may be disposed to form a grid pattern on the X-Y plane or in a zigzag shape in one direction. The channel structures CH may penetrate the gate electrodes 185, may extend in a vertical direction perpendicular to the upper surface of the second substrate 200, for example, in the Z-direction, and may have a pillar shape and an inclined side surface of which a width decreases toward the second substrate 200 depending on an aspect ratio. As illustrated in FIG. 2, the channel structures CH may have a circular shape having a first diameter W1, which is the largest width on an upper end.

Each of the channel structures CH may have a form in which lower and upper vertical structures CH1 and CH2 penetrating the lower gate stack group and the upper gate stack group of the gate electrodes 185 in the Z-direction, respectively, are connected to each other, and may have a bent portion due to a difference or change in a width of a lower surface of the upper vertical structure CH2 and a width of an upper surface of the lower vertical structure CH1 in the connection region.

Each of the channel structures CH may include a filling insulating layer 130, a channel layer 150, a data storage structure 160, and a blocking structure 170 in a channel hole penetrating the stack structure in the Z-direction.

The filling insulating layer 130 may be positioned in a center O of a channel hole filled by the channel structure CH, and may have a pillar shape extending in the Z-direction. The filling insulating layer 130 may partially penetrate the second substrate 200, and may be electrically and physically spaced apart from the second substrate 200.

The filling insulating layer 130 may have a shape in which a width decreases toward the second substrate 200 due to a high aspect ratio, and a width may change abruptly or non-consecutively along the bent portion of the channel structure CH in the channel structure CH. The filling insulating layer 130 may include a silicon oxide film.

The channel layer 150 may be disposed to have a channel thickness Ts while enclosing the filling insulating layer 130 between an internal side surface of the data storage structure 160 and an external side surface of the filling insulating layer 130. Accordingly, the channel layer 150 may be disposed consecutively in the lower channel structure CH1 and the upper channel structure CH2 so as to extend from an upper end of the channel structure CH to a lower end along the channel hole. Accordingly, the upper end of each channel layer 150 may be positioned at a level higher than a level of the upper surface of the filling insulating layer 130. The channel layer 150 may be in contact with the first horizontal conductive layer 202 through an external side surface in a contact region including a region at a level corresponding to the first horizontal conductive layer 202. Accordingly, the channel layer 150 may be electrically connected to the source structure SS.

The channel layer 150 may include a semiconductor material, such as polycrystalline silicon or single crystal silicon, and the semiconductor material may be an undoped material, or a material including P-type or N-type impurities. The channel layer 150 may include a semiconductor material. For example, the channel layer 150 may include at least one of doped silicon, undoped silicon, doped poly silicon, undoped poly silicon, or an oxide semiconductor. The oxide semiconductor may be indium gallium zinc oxide (IGZO), but the present disclosure is not limited thereto. For example, the oxide semiconductor may include at least one of indium tungsten oxide (ITO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The data storage structure 160 may be further included on the external side surface of the channel layer 150 of the channel structures CH, and the data storage structure 160 may be disposed in a region other than a contact region in which the first horizontal conductive layer 202 and the channel layer 150 are in contact with each other in the channel hole. In the contact region, the data storage structure 160 may be partially removed such that the channel layer 150 may be exposed.

The data storage structure 160 may include a plurality of stack structures.

The data storage structure 160 may include a tunneling layer 161 and a data storage layer 165 on the external side surface of the channel layer 150.

The tunneling layer 161 may surround the external side surface of the channel layer 150 and may be disposed between the channel layer 150 and the data storage layer 165. The tunneling layer 161 may tunnel electrons to the data storage layer 165, and may include, for example, silicon oxide (SiO₂), silicon oxynitride (SiON), or a combination thereof.

The data storage layer 165 may be disposed to have a fourth thickness T4 between the tunneling layer 161 and the blocking structure 170, and may be a charge trapping layer which may store data using a charge trap. The data storage layer 165 may include at least one of SiN, SiON, SiO/SiN, SiO/SiON, SiO/AlO, SiO/HfO, SiO/SiN/SiO, or SiO/nano-crystal. Here, the terms such as SiO/SiN may indicate a stack structure of a material layer of SiN and a material layer of SiO.

The blocking structure 170 may surround the data storage structure 160, and may include a crystal seed layer 173 and an antiferroelectric layer 175.

The antiferroelectric layer 175 may be a dielectric layer having antiferroelectric properties and may be disposed between the gate electrodes 185 and the data storage layer 165.

FIG. 5 is a graph indicating characteristics of an antiferroelectric layer 175 according to one or more embodiments. As demonstrated by plot n1 in FIG. 5, when a specific electric field or more is applied, spontaneous polarization having strong polarity may be formed, such that a high saturation polarization may occur, and a strong attractive force may be applied to the data storage layer 165 by the saturation polarization. Consequently, electrons may be boosted to smoothly flow into the data storage layer 165. As shown in plot n2 in FIG. 5, when an electric field is not applied, the spontaneous polarization may be removed, and the antiferroelectric layer 175 may have no polarity. Thus, the antiferroeletric layer 175 may have antiferroelectric properties, and strong spontaneous polarization may occur only when an electric field greater than the specific electric field is applied. Consequently, spontaneous reset may be possible without back gate voltage.

The antiferroelectric layer 175 having such antiferroelectric properties may include hafnium-zirconium oxide (HZO), and may include HZO having a specific crystal structure among hafnium-zirconium oxides (HZO).

The antiferroelectric layer 175 may include HZO having a tetragonal crystal structure.

The notion that the antiferroelectric layer 175 has the tetragonal crystal structure may indicate that HZO may be crystallized into tetragonal, orthorhombic and monoclinic phases, and may be crystallized such that the surface may mainly have the tetragonal crystal structure, which may indicate that 50% or more, and 70% or more in one or more embodiments, of the crystal structure may have the tetragonal crystal structure.

When the antiferroelectric layer 175 includes HZO having the tetragonal crystal structure, hafnium and zirconium may have a higher concentration of zirconium, but the present disclosure is not limited thereto.

The antiferroelectric layer 175 may have a first thickness T1, and the first thickness T1 may be equal to or greater than the channel thickness Ts of the channel layer 150, and may be twice the channel thickness Ts or less. The first thickness T1 of the antiferroelectric layer 175 may satisfy 5 nm to 10 nm, but the present disclosure is not limited thereto.

Generally, when the antiferroelectric layer 175 is applied as a dielectric layer, the antiferroelectric layer 175 may have antiferroelectric properties only in a state in which the layer has a large thickness, but the antiferroelectric layer 175 in one or more embodiments may control the crystal structure to have antiferroelectric properties while satisfying an extremely reduced thickness.

To this end, a crystal seed layer 173 may be further included on an interfacial surface of the antiferroelectric layer 175.

The crystal seed layer 173 may act as a crystal inducing layer to induce the tetragonal crystal structure of the antiferroelectric layer 175 during crystallization of the antiferroelectric layer 175.

The crystal seed layer 173 may be one of Y₂O₃, CeO₂, La₂O₃, or CaO, and may include iridium oxide (Y₂O₃).

The crystal seed layer 173 may be disposed on one side surface of the antiferroelectric layer 175, but the present disclosure is not limited thereto, and the crystal seed layer 173 may be disposed on both an internal side surface and an external side surface of the antiferroelectric layer 175.

The crystal seed layer 173 may have a second thickness T2 smaller than the first thickness T1, and the second thickness T2 may be an extremely reduced thickness and may satisfy ¼ to 1/10 of the first thickness T1, and ⅕ of the first thickness T1. When the antiferroelectric layer 175 has a thickness of 5 nm to 10 nm, the crystal seed layer 173 may have a thickness of 1 nm or more.

The crystal seed layer 173 may be iridium oxide. When crystallizing through annealing, Y³⁺ ions may be replaced in the Hf⁴⁺ and Zr⁴⁺ sites of the HZO lattice, such that oxygen vacancies may be formed, and compressive stress may be induced, which may contribute to stabilizing HZO into the tetragonal crystal structure.

In crystallization of when iridium oxide is present, in the crystal structure of HZO, the tetragonal crystal structure, which is a (110) crystal structure, may be induced.

As described above, by inducing the tetragonal crystal structure of the antiferroelectric layer 175 by including the crystal seed layer 173, stable antiferroelectric properties may be ensured despite the reduced thickness of the antiferroelectric layer 175.

The first dielectric layer 171 may be further included between the antiferroelectric layer 175 and the data storage structure 160.

The first dielectric layer 171 may include a material having a permittivity greater than that of the tunneling layer 161, and less than a permittivity in saturation polarization of the antiferroelectric layer 175, and aluminum oxide (Al₂O₃) may be included, but the present disclosure is not limited thereto.

The first dielectric layer 171 may be disposed between the data storage structure 160 and the crystal seed layer 173 as illustrated in FIG. 4, but the present disclosure is not limited thereto, and the first dielectric layer 171 may have a thickness greater than the second thickness T2 and less than the first thickness T1, and may have a thickness substantially the same as the channel thickness Ts, for example. The first dielectric layer 171 may be disposed between the crystal seed layer 173 and the data storage layer 165 and may increase retention efficiency and may increase a memory window by increasing a change in threshold voltage.

As described above, when the center of the filling insulating layer 130 is defined as the channel center O of the channel structure CH, the channel layer 150, the tunneling layer 161, the data storage layer 165, the first dielectric layer 171, the crystal seed layer 173 and the antiferroelectric layer 175, which form a concentric circle centered at the channel center O, may be disposed in order in the channel structure CH, when viewed on the X-Y plane.

Each channel structure CH may further include a pad pattern 157. The pad pattern 157 may be disposed on an upper end of the channel structure CH and may be disposed on an upper surface of the filling insulating layer 130. The pad pattern 157 may be connected to a plug 147 of which a side surface is connected to the channel layer 150 and of which an upper surface is connected to the bitline 140. The pad pattern 157 may be disposed at a level higher than a level of the upper gate electrode 185U among the gate electrodes 185. The pad pattern 157 may include a conductive material, for example, doped polysilicon having an N-type conductivity.

The connection between the pad pattern 157 and the bitlines 140 may be formed by the plugs 147, and the plugs 147 may be disposed one by one on the channel structures CH, respectively, and may be physically and electrically connected to the channel layers 150, respectively. The plugs 147 may have a cylindrical shape and may have an inclined side surface having a width decreasing toward the second substrate 200 depending on an aspect ratio.

An upper interconnection structure including bitlines 140 may be connected to the plugs 147, may extend in the Y-direction, and may be electrically connected to each of the channel structures CH. The upper interconnection structure may be the bitlines 140 or an interconnection structure electrically connected thereto.

The upper interconnection structure may include a conductive material, for example, tungsten (W), copper (Cu), aluminum (Al), or the like, and each element may further include a diffusion barrier including at least one of titanium (Ti), titanium nitride (TiN), tantalum (Ta), tantalum nitride (TaN), or tungsten nitride (WN). According to one or more embodiments, the number of layers and the arrangement patterns of the upper interconnection structure may be varied.

In the extended region neighboring to the cell region, the gate electrodes 185 may form step structures in the X-direction in the gate pad regions, respectively. The step structure may be a staircase structure relatively adjacent to the cell region and having a level decreasing in the X-direction, but the present disclosure is not limited thereto, and the step structure may be a staircase structure disposed relatively far from the cell region and having a level increasing in the X-direction. In the step structure, the gate electrodes 185 may be connected to contact plugs.

In a lower portion of the upper insulating layer 190, the cell region insulating layers may be disposed to cover the stack structures, respectively. The cell region insulating layers may be formed of an insulating material, and may include a plurality of insulating layers. When the cell region insulating layers include the same material as that of the interlayer insulating layers 120, the interfacial surface with the interlayer insulating layers 120 may not be distinct.

As illustrated in FIG. 2, FIG. 3, and FIG. 4, in the channel structure CH, the data storage structure 160 may include a charge trapping layer, and an antiferroelectric layer 175 for boosting the same may be included in the blocking structure 170, such that the memory window may be expanded by the negative capacitance effect.

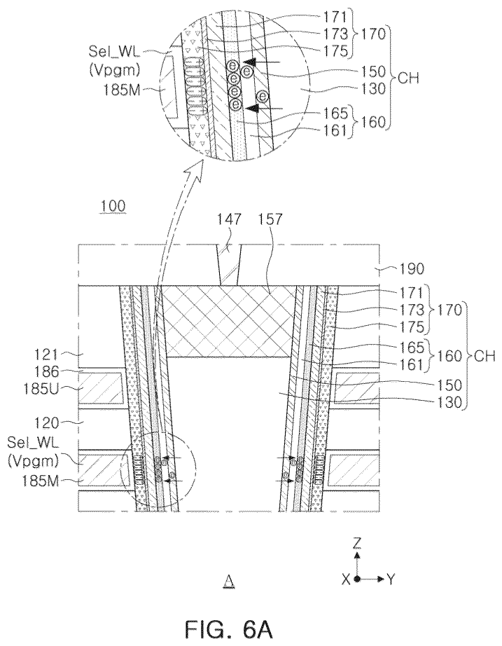

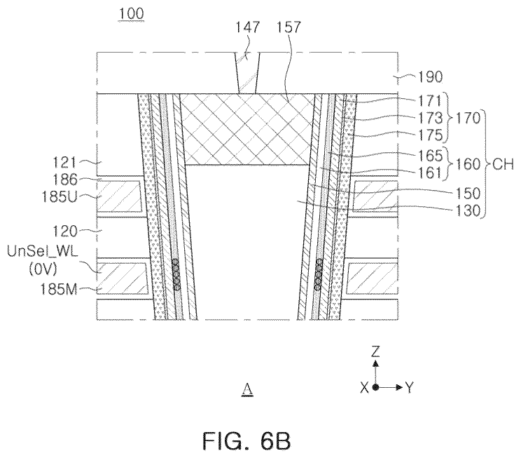

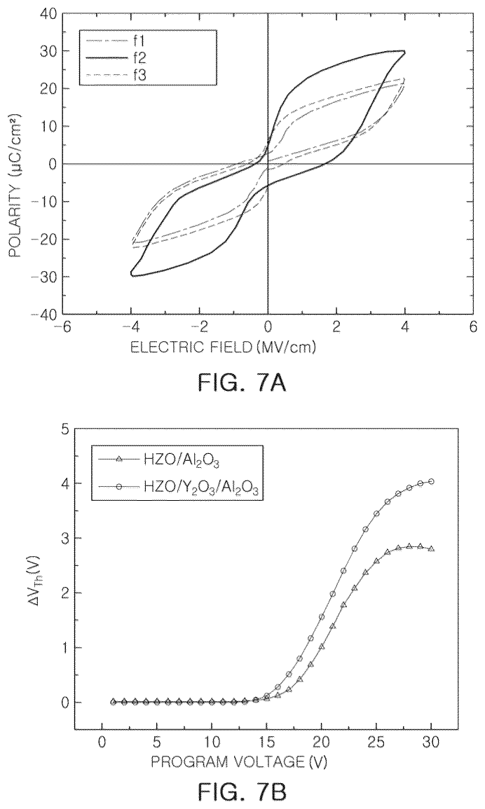

Hereinafter, operation of the semiconductor device 100 including a memory cell will be described with reference to FIG. 6A, FIGS. 6B, 7 FIG. A, and FIG. 7B.

FIG. 6A is a diagram illustrating a state during a program operation of a semiconductor device according to one or more embodiments, and FIG. 6B is a diagram illustrating a state after the program operation. FIG. 7A and FIG. 7B are graphs illustrating characteristics of a dielectric structure of the semiconductor device according to one or more embodiments.

When an electric field of a predetermined size is applied to an antiferroelectric layer 175, charge distribution may become non-centrosymmetric, and the antiferroelectric layer 175 may have spontaneous dipole (electric dipole), that is, spontaneous polarization (n1 in FIG. 5). Such spontaneous polarization may reach a maximum value of saturation polarization in an electric field of a specific level or more, and may have an extremely large permittivity.

Referring to FIG. 6A, during a program (e.g., read or write) operation, the channel layer 150 in the memory cell may be depleted by a program voltage Vpgm applied to the gate electrode 185, and depending on a voltage difference between the program voltage Vpgm applied to the gate electrode 185 and the channel layer 150, the antiferroelectric layer 175 may reach saturation polarization. The program operation may include applying a program voltage Vpgm greater than 0 V to the wordline WL, that is, the gate electrode 185 of a selected memory cell, grounding (0 V) the bitline BL and the channel layer 150 and lowering a threshold voltage of the selected memory cell.

In the program operation, by applying the program voltage Vpgm of about 20 V or more to the gate electrode 185 and grounding the bitline BL and the channel layer 150 to 0 V, a strong saturation polarization may be formed in the antiferroelectric layer 175. Accordingly, a strong attractive force may be applied to the adjacent data storage layer 165. Due to the strong attractive force applied to the data storage layer 165, a phenomenon similar to a Fermi level of the data storage layer 165, which is a dielectric layer, becoming relatively lowered, may occur. That is, a negative capacitance phenomenon may occur such that more electrons may move from the channel layer 150 to the data storage layer 165. Accordingly, a large number of electrons may be trapped in the data storage layer 165 such that a programmed state in which data is stored may be completed.

In this case, the neighboring cells not programmed may maintain the gate electrode 185 in a floating state, and the corresponding antiferroelectric layer 175 may maintain a state such as n2 in FIG. 5, in which spontaneous polarization does not occur.

As in FIG. 6B, when the program is terminated, a ground voltage of 0 V may be applied to the selected gate electrode 185, and the antiferroelectric layer 175 maintaining saturation polarization may change to the state of n2 in FIG. 5. That is, the antiferroelectric layer 175 may lose spontaneous polarization and may function as a general dielectric layer. Accordingly, similarly to the regions of the antiferroelectric layer 175 corresponding to the other unselected gate electrodes 185, the antiferroelectric layer 175 may change to a state in which spontaneous polarization is not formed. In this case, the electrons trapped in the data storage layer 165 may be maintained, such that the data storage layer 165 may maintain the programmed state.

Accordingly, the high saturation polarization of the antiferroelectric layer 175 may not be maintained for a lengthy period of time, and may be formed only during the program and disappear, such that spontaneous polarization may not affect the neighboring cells, and the element reliability may be improved, and operation may be performed without a back gate voltage.

As described above, the memory window may be expanded by the negative capacitance effect of the data storage layer 165 due to a high saturation polarization of the antiferroelectric layer 175.

FIG. 7A illustrates polarization characteristics of various antiferroelectric, in which the second graph (f2) includes the antiferroelectric layer 175, which is a blocking structure 170 having a thickness of 5.8 nm, and the crystal seed layer 173 in one or more embodiments, the third graph (f3) indicates the polarization characteristics of the antiferroelectric layer 175 having a thickness of 5.9 nm implemented with only HZO without the crystal seed layer 173, and the first graph (f1) indicates the polarization characteristics of the antiferroelectric layer 175 having a thickness of 5.1 nm implemented with only HZO without the crystal seed layer 173.

Comparing the three graphs (f1, f2, and f3) in FIG. 7A, it may be confirmed that the second graph (f2) in one or more embodiments may have the largest saturation polarization despite a reduced thickness, and clearly exhibits antiferroelectric properties close to 0 V such that spontaneous polarization is almost eliminated in the absence of an electric field.

FIG. 7B illustrates a change in threshold voltage of the blocking structure 170 when the crystal seed layer 173 is present and when the crystal seed layer 173 is not present. It may be confirmed that the change in threshold voltage is larger when the crystal seed layer 173 is present, and when the change in threshold voltage is large, the memory window may be large.

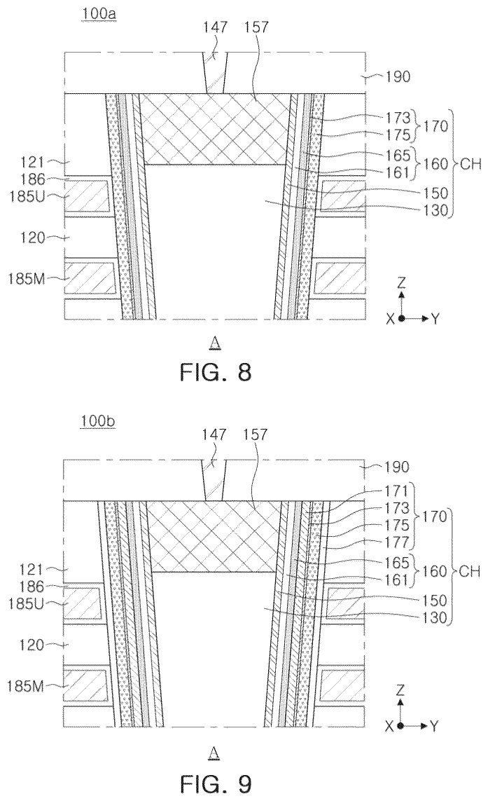

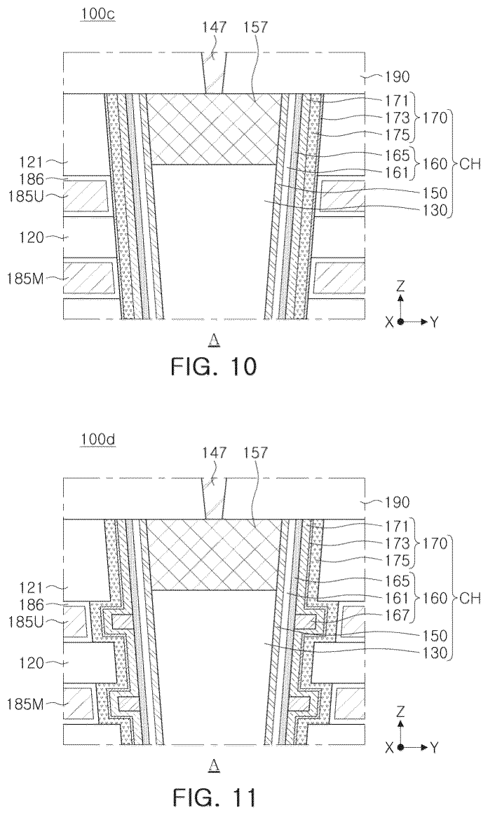

FIG. 8, FIG. 9, FIG. 10, and FIG. 11 are enlarged diagrams illustrating a portion of a semiconductor device according to one or more embodiments, illustrating a region corresponding to region “A” in FIG. 3.

Referring to FIG. 8, a semiconductor device 100a may be the same as the channel structure CH in FIG. 4 other than the configuration in which the first dielectric layer 171 is not included in the blocking structure 170.

In the semiconductor device 100a in FIG. 8, the blocking structure 170 may include an antiferroelectric layer 175 and a crystal seed layer 173.

The crystal seed layer 173 may be disposed between the data storage layer 165 and the antiferroelectric layer 175, and may be disposed to surround an external side surface of the data storage layer 165.

A permittivity of the crystal seed layer 173 may have a permittivity between the data storage layer 165 and the antiferroelectric layer 175, such that the crystal seed layer 173 may be disposed directly on the data storage layer 165. In this case, a thickness of the crystal seed layer 173 may be greater than the second thickness T2, and may be less than the first thickness T1, but the present disclosure is not limited thereto.

Referring to FIG. 9, the semiconductor device 100b may be the same as the channel structure CH in FIG. 4 other than the configuration in which the second dielectric layer 177 is further included.

The second dielectric layer 177 may be an insulating layer, may be disposed between the gate electrodes 185 and the antiferroelectric layer 175, and may be disposed in a cylindrical shape or a cylinder shape covering an external side surface of the antiferroelectric layer 175. The second dielectric layer 177 may be in contact with the antiferroelectric layer 175 through an internal side surface, and may be in contact with the gate electrodes 185 through the external side surface. The second dielectric layer 177 may prevent carriers from moving to the antiferroelectric layer 175 and/or the gate electrodes 185, or may prevent materials from diffusing. Accordingly, the spontaneous polarization state in the antiferroelectric layer 175 may be stably maintained, and the ferroelectric properties of the antiferroelectric layer 175 may be stably maintained.

The second dielectric layer 177 may include an insulating material. The second dielectric layer 177 may include an insulating material, such as silicon oxide, similarly to the tunneling layer 161, but the present disclosure is not limited thereto.

Referring to FIG. 10, the semiconductor device 100c may have the same channel structure CH in FIG. 4, other than the positions of the crystal seed layer 173 and the antiferroelectric layer 175.

In the semiconductor device 100c in FIG. 10, the antiferroelectric layer 175 and the crystal seed layer 173 may be disposed to be in contact with each other, the antiferroelectric layer 175 may be disposed on an inner side, and the crystal seed layer 173 may be disposed on an outer side from the center O of the channel structure CH. In FIG. 10, the antiferroelectric layer 175 may be disposed to surround an external side surface of the first dielectric layer 171, and the crystal seed layer 173 may be disposed to surround an external side surface of the antiferroelectric layer 175.

The arrangement may further accelerate crystallization by stacking the crystal seed layer 173 in the channel hole first and stacking the antiferroelectric layer 175 on the crystal seed layer 173 in the process order.

Referring to FIG. 11, in the channel structure CH of the semiconductor device 100d, the structure of the data storage structure 160 may be different from the example embodiment in FIG. 4.

The data storage structure 160 may further include a floating electrode 167 between the first dielectric layer 171 and the data storage layer 165. The floating electrode 167 may be a material different from a material of the data storage layer 165.

The floating electrode 167 may include a conductive material, and may include a metal material such as tungsten, tungsten nitride, titanium nitride, or tantalum nitride.

The floating electrodes 167 may be disposed to overlap each gate electrode 185 in the XY-direction, may be disposed in a ring shape on one channel structure CH, and may be spaced apart from each other in the Z-direction.

The blocking structure 170 may be bent along an external side surface of the floating electrodes 167.

Specifically, the first dielectric layer 171 may be disposed along the external side surface of the floating electrodes 167, and the first dielectric layer 171 may cover an upper surface and an external side surface consecutively along the external side surface of the floating electrodes 167, and may also cover the external side surface of the data storage layer 165 exposed between the floating electrodes 167.

The crystal seed layer 173 may be disposed along the external side surface of the first dielectric layer 171, and the antiferroelectric layer 175 may be disposed along the external side surface of the crystal seed layer 173. Accordingly, the crystal seed layer 173 and the antiferroelectric layer 175 may be bent along the shape of the external side surface of the floating electrodes 167.

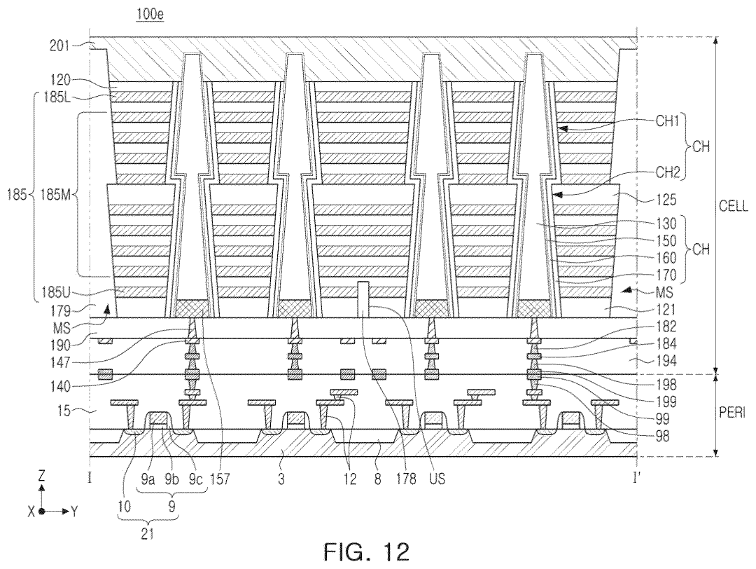

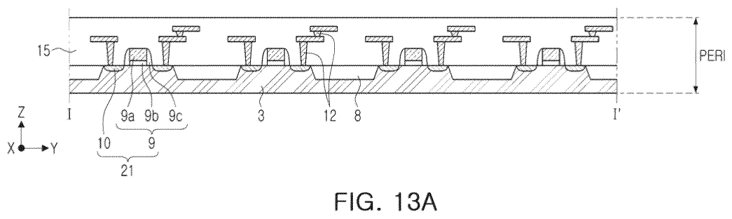

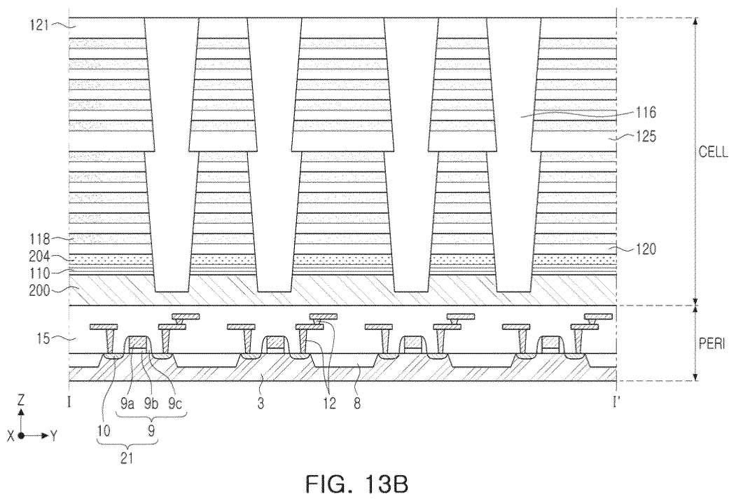

Referring to FIG. 12, the semiconductor device 100e may include a first semiconductor structure PERI and a second semiconductor structure CELL bonded to each other by a wafer bonding method.

The description of the second region PERI described above with reference to FIG. 2, FIG. 3, FIG. 4 may be applied to the first semiconductor structure PERI. However, the first semiconductor structure PERI may further include first bonding vias 98 and first bonding pads 99, which are bonding structures. The first bonding vias 98 may be disposed in an upper portion of circuit interconnection lines 12 in an uppermost portion, and may be connected to the circuit interconnection lines 12. At least a portion of the first bonding pads 99 may be connected to the first bonding vias 98 on the first bonding vias 98. The first bonding pads 99 may be connected to the second bonding pads 199 of the second semiconductor structure CELL. The first bonding pads 99 may provide an electrical connection path due to bonding between the first semiconductor structure PERI and the second semiconductor structure CELL together with the second bonding pads 199. The first bonding vias 98 and the first bonding pads 99 may include a conductive material, for example, copper (Cu).

As for the second semiconductor structure CELL, unless otherwise indicated, the description of the first region CELL referring to FIG. 2, FIG. 3, FIG. 4 may be applied. The second semiconductor structure CELL may further include lower contact plugs 182 and lower interconnection lines 184, which are interconnection structures, and may further include second bonding vias 198 and second bonding pads 199, which are bonding structures. The second semiconductor structure CELL may further include a passivation layer covering the upper surface of the plate layer 201.

Lower contact plugs 182 may be disposed below the upper interconnection structure including bitlines 140, and may connect the upper interconnection structure to lower interconnection lines 184. However, in one or more embodiments, the number of layers and arrangement of the contact plugs and the interconnection lines included in the interconnection structure may be varied. The lower contact plugs 182 and the lower interconnection lines 184 may be formed of a conductive material, and may include at least one of tungsten (W), aluminum (Al), or copper (Cu), for example.

Second bonding vias 198 and second bonding pads 199 may be disposed below the lower interconnection lines 184 in a lowermost portion. The second bonding vias 198 may be connected to the upper interconnection structure and the second bonding pads 199, and the second bonding pads 199 may be bonded to the first bonding pads 99 of the first semiconductor structure S1. The second bonding vias 198 and the second bonding pads 199 may include a conductive material, for example, copper (Cu).

The first semiconductor structure PERI and the second semiconductor structure CELL may be bonded to each other by copper (Cu)-copper (Cu) bonding by the first bonding pads 99 and the second bonding pads 199. In addition to the copper (Cu)-copper (Cu) bonding, the first semiconductor structure PERI and the second semiconductor structure CELL may further be bonded to each other by dielectric-dielectric bonding. The dielectric-dielectric bonding may be bonding by dielectric layers forming a portion of each of the lower capping layer 15 and the cell region insulating layer 194, and surrounding each of the first bonding pads 99 and the second bonding pads 199. Accordingly, the first semiconductor structure PERI and the second semiconductor structure CELL may be bonded to each other without an adhesive layer.

The passivation layer may be disposed on an upper surface of the plate layer 201 and may protect the semiconductor device 100e. The passivation layer may include at least one of an insulating material, for example, silicon oxide, silicon nitride, or silicon carbide, and may include a plurality of insulating layers in one or more embodiments.

In the example embodiment, the second semiconductor structure CELL may not include the first and second horizontal conductive layers 202 and 204 (see FIG. 3). The channel structures CH may be directly connected to the plate layer 201 with the channel layers 150 exposed through an upper end. However, the electrical connection between the channel structures CH and the common source line may be varied in one or more embodiments, and the channel structures CH and the source structure SS may have a structure as in the example embodiment in FIG. 3.

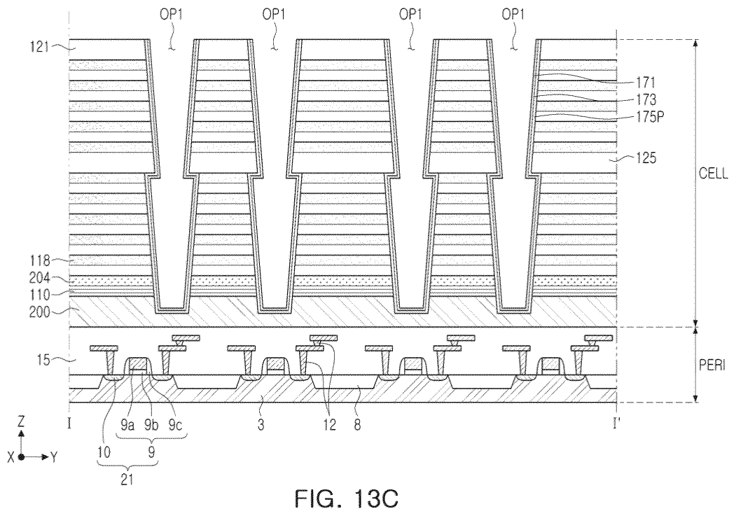

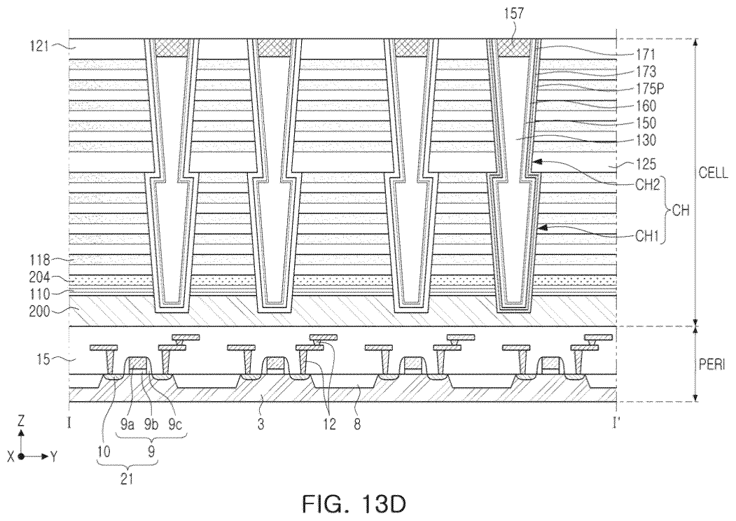

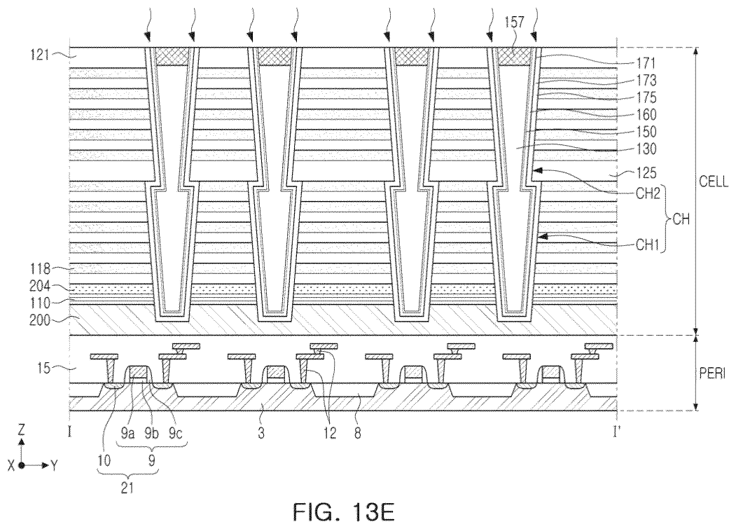

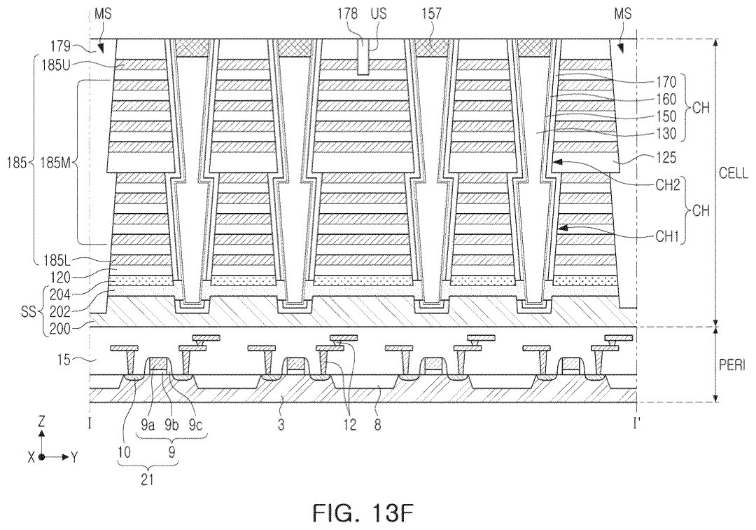

In the description below, a method of manufacturing a semiconductor device 100 according to one or more embodiments will be described with reference to FIGS. 13A to 13F. FIG. 13A to FIG. 13F are cross-sectional diagrams illustrating regions corresponding to FIG. 3 to describe a method of manufacturing a semiconductor device according to one or more embodiments.

Referring to FIG. 13A, circuit elements 21, a lower interconnection structure 12, element isolation layers 8, and a lower capping layer 15 forming a second region PERI may be formed on a first substrate 3.

First, element isolation layers 8 may be formed in the first substrate 3, and circuit gate dielectric layer 9b and circuit gate electrode 9a may be formed in order on the first substrate 3. The element isolation layers 8 may be formed, for example, by a shallow trench isolation (STI) process. The circuit gate dielectric layer 9b may be formed on the first substrate 3, and the circuit gate electrode 9a may be formed on the circuit gate dielectric layer 9b. The circuit gate dielectric layer 9b and the circuit gate electrode 9a may be formed using atomic layer deposition (ALD) or chemical vapor deposition (CVD). The circuit gate dielectric layer 9b may be formed of silicon oxide, and the circuit gate electrode 9a may be formed of at least one of polycrystalline silicon or a metal silicide layer, but the present disclosure is not limited thereto. Thereafter, spacer layers may be formed on both sidewalls of the circuit gate dielectric layer 9b and the circuit gate electrode 9a, and impurities may be injected into the active region of the first substrate 3 on both sides of the circuit gate electrode 9a and source/drain regions 10 may be formed.

Lower contact plugs of the lower interconnection structure 12 may be formed by forming a portion of the lower capping layer 15, etching and removing a portion thereof, and filling a conductive material. Lower interconnection lines may be formed, for example, by depositing a conductive material and patterning the material.

The lower capping layer 15 may include a plurality of insulating layers. The lower capping layer 15 may become a portion in each of the processes of forming the lower interconnection structure 12. Accordingly, a second region PERI may be formed.

Referring to FIG. 13B, a second substrate 200 may be formed on the second region PERI, and a mold structure and vertical sacrificial structures 116 may be formed on the second substrate 200.

The second substrate 200 may include a semiconductor material, for example, a group IV semiconductor, a group III-V compound semiconductor, or a group II-VI compound semiconductor.

A horizontal sacrificial structure 110 may be formed on the second substrate 200, and a sacrificial insulating layer 118 and an interlayer insulating layer 120 may be formed. The horizontal sacrificial structure 110 may be formed by stacking the first horizontal sacrificial layers and the second horizontal sacrificial layer in order.

The substrate insulating layer may be formed to penetrate the second substrate 200 in some regions including regions in which contact plugs are disposed. The substrate insulating layer may be formed by removing a portion of the second substrate 200, the horizontal insulating layer 110, and the second horizontal conductive layer 204, and filling an insulating material. After filling the insulating material, a planarization process may further be performed using a chemical mechanical polishing (CMP) process. Accordingly, an upper surface of the substrate insulating layer may be substantially coplanar with an upper surface of a second horizontal conductive layer 204. Sacrificial insulating layers 118 and interlayer insulating layers 120 may be alternately stacked on the second horizontal conductive layer 204 and a lower mold structure may be formed, and the sacrificial insulating layers 118 and the interlayer insulating layers 120 may be alternately stacked and an upper mold structure may be formed. A portion of the sacrificial insulating layers 118 may be replaced with gate electrodes 185 through a subsequent process.

The sacrificial insulating layers 118 may be formed of a material different from that of the interlayer insulating layers 120, and may be formed of a material etched having etch selectivity under specific etching conditions with respect to the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120 selected from among silicon, silicon oxide, silicon carbide, and silicon nitride. A thickness of the interlayer insulating layers 120 may not be the same as described above with reference to FIG. 2 FIG. 3 and FIG. 4. For example, the intermediate interlayer insulating layer 125 may have a relatively greater thickness than that of the other interlayer insulating layers 120. The number of the interlayer insulating layers 120 and the sacrificial insulating layers 118 may be varied from the illustrated example.

A staircase structure may be formed by repeatedly performing a photolithography process and an etching process for the sacrificial insulating layers 118 and the interlayer insulating layers 120.

The vertical sacrificial structures 116 may be formed in the region in which the channel structures CH are disposed so as to penetrate the lower mold structure. The vertical sacrificial structures 116 may be formed by anisotropically etching the lower mold structure of the sacrificial insulating layers 118 and the interlayer insulating layers 120 using a mask layer, and may be formed by forming lower channel holes and filling the holes. The vertical sacrificial structure 116 may include a semiconductor material such as polycrystalline silicon. According to one or more embodiments, the vertical sacrificial structure 116 may include at least one of silicon oxide, silicon nitride, or silicon oxynitride. Lower contact sacrificial layers may also be formed together with the vertical sacrificial structure 116.

Referring to FIG. 13C, by removing the vertical sacrificial structures 116, channel holes, which are first openings OP1, may be formed in the region corresponding to each channel structure CH.

In the first openings OP1, preliminary antiferroelectric layers 175P, crystal seed layers 173, and first dielectric layers 171 may be formed consecutively.

Specifically, in the chamber, HfO₂ and ZrO₂ may be injected at a ratio of 1:4, and by performing atomic layer deposition (ALD) at a temperature of 250° C., preliminary antiferroelectric layers 175P may be deposited with a first thickness T1 on a sidewall and a bottom surface of the first openings OP1. In this case, the formed HZO material may have an amorphous structure, or may be in a state in which various crystal structures are mixed.

Consecutively, in the same chamber, at the same 250° C., Y₂O₃ may be deposited to an atomic layer, such that a crystal seed layer 173 may be formed to have a second thickness T2.

Consecutively, in the same chamber, at the same 250° C., aluminum oxide may be deposited to an atomic layer on the crystal seed layer 173 and may be deposited to have a third thickness T3. Accordingly, a blocking structure 170 including a preliminary antiferroelectric layer 175P may be formed in a chamber, and may be deposited in the same chamber in the same manner at the same temperature.

Thereafter, as illustrated in FIG. 13D, a channel structure CH may be formed.

Specifically, a data storage layer 165, which is a data storage structure 160, may be deposited, and a tunneling layer 161 may be formed on the data storage layer 165. A channel layer 150 may be formed on the tunneling layer 161, and a filling insulating layer 130 may be formed in a center of the channel structure CH exposed by the channel layer 150. A pad pattern 157 may be formed in an upper portion of the filling insulating layer 130.

The data storage layer 165 and the tunneling layer 161 may be stacked in order in the channel hole. The layers forming the data storage structure 160 may conformally extend along internal sidewalls and bottom surfaces of the blocking structure 170 of the first opening OP1 to have a uniform thickness using an atomic layer deposition or chemical vapor deposition (CVD) process.

The channel layer 150 may be formed on the data storage structure 160 in the channel structures CH. The channel layer 150 may conformally extend on the data storage structure 160. The filling insulating layer 130 may include at least one of silicon nitride and silicon oxynitride. The filling insulating layer 130 may fill the first opening OP1. In this case, an etch-back process may be performed such that the filling insulating layer 130 may be etched to a predetermined depth, and a conductive material may be filled, thereby forming a pad pattern 157. The pad pattern 157 may be formed by forming a pad pattern layer to cover an upper portion of the uppermost interlayer insulating layer 121 while filling a space in the channel structure CH, and planarizing until the uppermost interlayer insulating layer 121 is exposed. The pad pattern 157 may include doped polycrystalline silicon.

As illustrated in FIG. 13F, by performing annealing, the preliminary antiferroelectric layer 175P may be crystallized.

Specifically, by performing annealing at a temperature and pressure of 600° C. and 1 torr in a nitrogen (N2) atmosphere, the preliminary antiferroelectric layer 175P may be crystallized. In this case, the preliminary antiferroelectric layer 175P may be crystallized to have a tetragonal crystal structure by implanting iridium atoms from the crystal seed layer 173. Accordingly, the antiferroelectric layer 175 may be formed, and crystallization may be performed to have a high saturation polarization also in the first thickness T1, such that element reliability may be ensured. During the annealing, a portion of the channel layer 150 may also be crystallized.

Thereafter, as in FIG. 13F, an isolation opening may be formed in the isolation region MS, and may be replaced with gate electrodes 185.

First, the isolation opening may penetrate the mold structure of the sacrificial insulating layers 118 and the interlayer insulating layers 120, may penetrate the second horizontal conductive layer 204 in a lower portion, and may extend in the X-direction. Thereafter, sacrificial spacer layers may be formed in the isolation opening, and the second horizontal sacrificial layer may be exposed by an etch-back process. The exposed second horizontal sacrificial layer may be selectively removed, and the upper and lower first horizontal sacrificial layers may be removed. The horizontal sacrificial structure 110 may be removed, for example, by a wet etching process. During the process of removing the horizontal sacrificial structure 110, the exposed data storage structure 160 may also be partially removed from the region from which the second horizontal sacrificial layer is removed, thereby forming a contact region in which an external side surface of the channel layer 150 is exposed.

Thereafter, the first horizontal conductive layer 202 may be formed by depositing a conductive material in the region from which the horizontal sacrificial structure 110 is removed, and a lower spacer may be formed by surrounding a bottom surface from the second horizontal conductive layer 204. The lower spacer may include a material having etch selectivity with the sacrificial insulating layer 118 and may include silicon oxide.

The sacrificial insulating layers 118 may be selectively removed with respect to the interlayer insulating layers 120, for example, using wet etching, through the isolation opening. Accordingly, a plurality of tunnel portions may be formed between the interlayer insulating layers 120, and may be replaced with gate electrodes 185.

The gate electrodes 185 may be formed, respectively, by depositing a conductive material on the plurality of tunnel portions through the isolation opening. The conductive material may include metal, polycrystalline silicon, or metal silicide material. After forming the gate electrodes 185, the conductive material deposited in the isolation opening may be removed through an additional process, and an insulating material may be filled, thereby forming an isolation region MS, and an upper isolation region US may also be formed.

As illustrated in FIG. 3, the upper insulating layer 190 may be further formed, and plugs 147 penetrating the upper insulating layer 190 and connected to the channel structures CH may be formed.

The plugs 147 may be directly connected to the pad patterns 157. In one or more embodiments, the plugs 147 may be formed to be partially recessed into the pad patterns 157. By forming upper interconnection structures including bitlines 140 on the plugs 147, a semiconductor device 100 may be manufactured.

According to one or more embodiments, a method of manufacturing a semiconductor device includes forming a mold structure by alternately stacking interlayer insulating layers and sacrificial insulating layers stacked in a first direction perpendicular to an upper surface of a substrate; forming a channel hole by penetrating the mold structure in the first direction; forming a preliminary antiferroelectric layer and a crystal seed layer on an inner side of the channel hole; forming a data storage layer, a channel layer and a filling insulating layer on the crystal seed layer and filling the channel hole; crystallizing the preliminary antiferroelectric layer from the crystal seed layer into an antiferroelectric layer having a tetragonal crystal structure by annealing; and removing the sacrificial insulating layers and replacing the sacrificial insulating layers with gate electrodes.

Forming the preliminary antiferroelectric layer may include depositing the preliminary antiferroelectric layer to have a thickness 1 to 2 times greater than a thickness of the channel layer.

The antiferroelectric layer may include hafnium-zirconium oxide (HZO) having a tetragonal crystal structure.

The preliminary antiferroelectric layer and the crystal seed layer may be formed by consecutive deposition in the same chamber.

The preliminary antiferroelectric layer and the crystal seed layer may be formed by atomic layer deposition.

The crystal seed layer may be formed by depositing at least one of Y₂O₃, CeO₂, La₂O₃, or CaO.

Forming the crystal seed layer may include depositing the crystal seed layer to have a thickness of ¼ to 1/10 of a thickness of the preliminary antiferroelectric layer.

The method may further include forming a dielectric layer between the data storage layer and the preliminary ferroelectric layer.

Forming the dielectric layer may include atomic layer deposition in the same chamber as the preliminary ferroelectric layer.

The dielectric layer may include aluminum oxide.

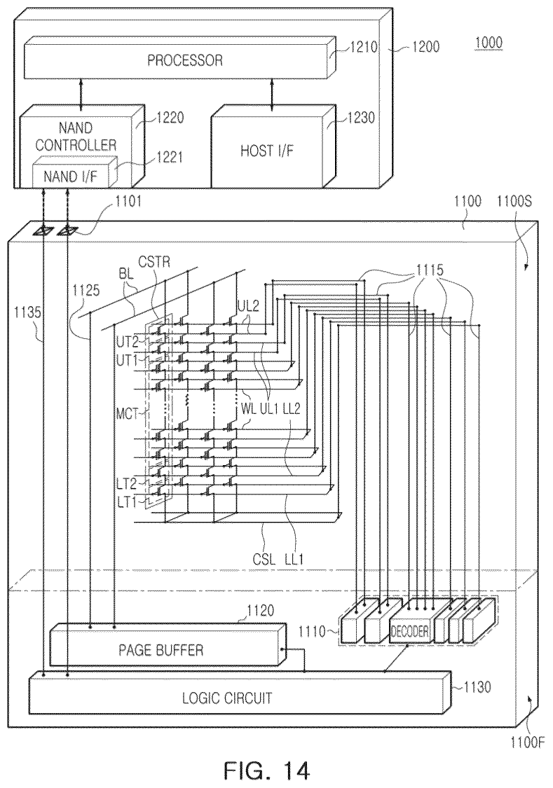

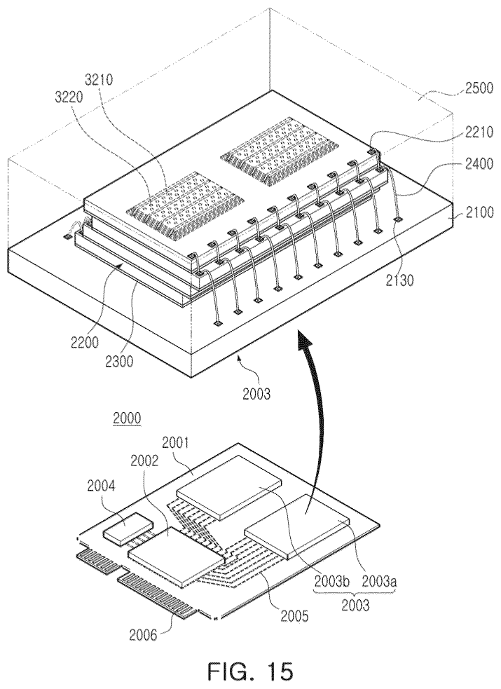

In the description below, a data storage system including a semiconductor device according to one or more embodiments will be described with reference to FIG. 14 and FIG. 15.

FIG. 14 is a diagram illustrating a data storage system including a semiconductor device according to one or more embodiments.

Referring to FIG. 14, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

In an embodiment, the data storage system 1000 may be an electronic system for storing data.

The semiconductor device 1100 may be a non-volatile memory device. For example, the semiconductor device 1100 may be a semiconductor device according to one of the example embodiments described above with reference to FIG. 2, FIG. 3, FIG. 4, FIG. 5, FIG. 8, FIG. 9, FIG. 10, FIG. 11, and FIG. 12. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure (PERI in FIG. 3) described above. The peripheral circuit (e.g., 21 in FIG. 3) described above may be transistors of the decoder circuit 1110, the page buffer 1120, and the logic circuit 1130.

The second structure 1100S may be a memory structure including a bitline BL, a common source line CSL, wordlines WL, first and second gate upper lines UL1 and UL2, first and second gate lower lines LL1 and LL2, and memory cell strings CSTR between the bitline BL and the common source line CSL.

The source structure SS described above may include a silicon layer having an N-type conductivity, and at least a portion of the source structure SS may form the common source line CSL.

In the second structure 1100S, each of the memory cell strings CSTR may include a plurality of memory cell transistors MCT disposed between lower transistors LT1 and LT2 adjacent to the common source line CSL, upper transistors UT1 and UT2 adjacent to the bitline BL, and the lower transistors LT1 and LT2 and the upper transistors UT1 and UT2. The number of lower transistors LT1 and LT2 and the number of upper transistors UT1 and UT2 may be varied in one or more embodiments.

The plurality of memory cell transistors MCT may include the intermediate gate electrodes 185M, which may be wordlines, the channel layer 150 of the channel structure CH, the filling insulating layer 130, the data storage layer 165, and the antiferroelectric layer 175 as described with reference to FIG. 3.

In one or more embodiments, the upper transistors UT1 and UT2 may include string select transistors, and the lower transistors LT1 and LT2 may include ground select transistors. The gate lower lines LL1 and LL2 may be configured as gate electrodes of the lower transistors LT1 and LT2, respectively. The wordlines WL may be configured as gate electrodes 185 of the memory cell transistors MCT, and the gate upper lines UL1 and UL2 may be configured as gate electrodes of the upper transistors UT1 and UT2, respectively.

The gate electrodes (185 in FIG. 3) described above may form the gate lower lines LL1 and LL2, the wordlines WL and the gate upper lines UL1 and UL2.

The common source line CSL, the first and second gate lower lines LL1 and LL2, wordlines WL, and the first and second gate upper lines UL1 and UL2 may be electrically connected to the decoder circuit 1110 through the first interconnections 1115 extending from the first structure 1100F to the second structure 1100S.

The bitlines 140 BL may be electrically connected to the page buffer 1120 through second interconnections 1125 extending from in the first structure 1100F to the second structure 1100S. The bitlines BL may be the bitlines 140 described above.

In the first structure 1100F, the decoder circuit 1110 and the page buffer 1120 may perform a control operation for at least one select memory cell transistor among a plurality of memory cell transistors MCT. The decoder circuit 1110 and the page buffer 1120 may be controlled by the logic circuit 1130.

The semiconductor device 1100 may further include an input/output pad 1101. The semiconductor device 1100 may communicate with the controller 1200 through the input/output pad 1101, electrically connected to the logic circuit 1130. The input/output pad 1101 may be electrically connected to the logic circuit 1130 through an input/output interconnection 1135 extending to the second structure 1100S in the first structure 1100F. Accordingly, the controller 1200 may be electrically connected to the semiconductor device 1100 through the input/output pad 1101 and may control the semiconductor device 1100.

The controller 1200 may include a processor 1210, a NAND controller 1220, and a host interface 1230. In one or more embodiments, the data storage system 1000 may include a plurality of semiconductor devices 1100, and in this case, the controller 1200 may control a plurality of semiconductor devices 1100.

The processor 1210 may control operations of the data storage system 1000 including the controller 1200. The processor 1210 may operate according to predetermined firmware and may access the semiconductor devices 1100 by controlling the NAND controller 1220. The NAND controller 1220 may include a controller interface 1221 handling communication with the semiconductor device 1100. Through the controller interface 1221, control commands for controlling the semiconductor device 1100, data to be written in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

FIG. 15 is a perspective diagram illustrating a data storage system including a semiconductor device in one or more embodiments.

Referring to FIG. 15 a data storage system 2000 in one or more embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number of the plurality of pins in the connector 2006 and the arrangement thereof may be varied depending on a communication interface between the data storage system 2000 and an external host. In one or more embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In one or more embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include a semiconductor device according to one or more embodiments described above with reference to FIG. 2, FIG. 3, FIG. 4, FIG. 5, FIG. 8, FIG. 9, FIG. 10, FIG. 11, and FIG. 12.

Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each of the semiconductor chips 2200 may include input/output pads 2210.

In one or more embodiments, the connection structure 2400 may be a bonding wire electrically connecting the input/output pads 2210 to the package upper pads 2130. Accordingly, in each of the first and second semiconductor packages 2003a and 2003b, the semiconductor chips 2200 may be electrically connected to each other by a bonding wire method and may be electrically connected to the package upper pads 2130 of the package substrate 2100. According to one or more embodiments, in each of the first and second semiconductor packages 2003a and 2003b, the semiconductor chips 2200 may be electrically connected to each other by a connection structure including a through-electrode (through silicon via, TSV) instead of the connection structure 2400 by a bonding wire method.

In one or more embodiments, the controller 2002 and the semiconductor chips 2200 may be included in a single package. For example, the controller 2002 and the semiconductor chips 2200 may be mounted on a separate interposer substrate from the main board 2001, and the controller 2002 and the semiconductor chips 2200 may be connected to each other by interconnections formed on the interposer substrate.

According to the aforementioned example embodiments, by including a dielectric structure applying an antiferroelectric layer which may enhance data storage by using spontaneous polarization, by having a high saturation polarization by a strong electric field during programming, electrons may be induced to be collected in the charge trapping layer. When the electric field is removed after programming, by functioning as a general insulating layer due to the characteristics of antiferroelectric properties in which spontaneous polarization is eliminated, electrons stored in the charge trapping layer may not be affected without a back gate voltage. Accordingly, the influence of the electric field on neighboring unselected cells may be reduced.

While one or more embodiments have been illustrated and described above, it will be configured as apparent to those skilled in the art that modifications and variations could be made without departing from the scope of the present disclosure as defined by the appended claims.

What is claimed is:

1. A semiconductor device comprising:
a source structure;
a stack structure comprising interlayer insulating layers and gate electrodes stacked in a first direction perpendicular to an upper surface of the source structure; and
a channel structure penetrating the stack structure and the source structure in the first direction, the channel structure comprising a channel layer, a data storage layer on the channel layer, and a blocking structure between the data storage layer and the gate electrodes,
wherein the blocking structure comprising an antiferroelectric layer comprising a first crystal structure.

2. The semiconductor device of claim 1, wherein the antiferroelectric layer comprises a tetragonal crystal structure.

3. The semiconductor device of claim 2, wherein the antiferroelectric layer comprises hafnium-zirconium oxide (HZO).

4. The semiconductor device of claim 1, wherein the antiferroelectric layer has a thickness one to two times greater than a thickness of the channel layer.

5. The semiconductor device of claim 1, wherein the blocking structure further comprises a crystal seed layer on at least one side surface of the antiferroelectric layer.

6. The semiconductor device of claim 5, wherein the crystal seed layer comprises at least one of Y₂O₃, CeO₂, La₂O₃ or CaO.

7. The semiconductor device of claim 5, wherein the crystal seed layer has a thickness one quarter to one tenth of a thickness of the antiferroelectric layer.

8. The semiconductor device of claim 1, wherein the blocking structure further comprises a dielectric layer between the data storage layer and the gate electrodes.

9. The semiconductor device of claim 8, wherein the dielectric layer has a permittivity lower than a permittivity of the antiferroelectric layer.

10. The semiconductor device of claim 8, wherein the dielectric layer comprises aluminum oxide.

11. The semiconductor device of claim 8,
wherein the channel structure further comprises a tunneling layer between the data storage layer and the channel layer, and
wherein the dielectric layer has a permittivity greater than a permittivity of the tunneling layer.

12. The semiconductor device of claim 8, wherein the blocking structure further comprises a crystal seed layer on at least one side surface of the antiferroelectric layer, and
wherein the dielectric layer is between the data storage layer and the crystal seed layer.

13. The semiconductor device of claim 1, wherein the data storage layer comprises a charge trapping layer.

14. A semiconductor device comprising:
a source structure;
a stack structure comprising interlayer insulating layers and gate electrodes stacked in a first direction perpendicular to an upper surface of the source structure, the stack structure comprising a channel hole penetrating the interlayer insulating layers and the gate electrodes in the first direction;
a filling insulating layer in a center of the channel hole;
a channel layer on an external side surface of the filling insulating layer;
a tunneling layer on an external side surface of the channel layer;
a charge trapping layer on the tunneling layer;
an antiferroelectric layer on the charge trapping layer, the antiferroelectric layer configured to have spontaneous polarization when a voltage is applied; and
a crystal seed layer on one side surface of the antiferroelectric layer,
wherein the antiferroelectric layer has a tetragonal crystal structure.

15. The semiconductor device of claim 14,
wherein the antiferroelectric layer comprises hafnium-zirconium oxide (HZO), and
wherein the crystal seed layer comprises at least one of Y₂O₃, CeO₂, La₂O₃ or CaO.

16. The semiconductor device of claim 14, wherein the antiferroelectric layer has a thickness one to two times greater than a thickness of the channel layer.

17. The semiconductor device of claim 14, wherein the crystal seed layer has a thickness one quarter to one tenth of a thickness of the antiferroelectric layer.

18. The semiconductor device of claim 14, wherein the charge trapping layer comprises silicon nitride.

19. The semiconductor device of claim 14, further comprising:
a dielectric layer having a permittivity between a permittivity of the antiferroelectric layer and a permittivity of the tunneling layer, wherein the dielectric layer is between the charge trapping layer and the gate electrodes.

20. A data storage system comprising:
a semiconductor device comprising an input/output pad; and
a controller connected to the semiconductor device through the input/output pad,
wherein the controller is configured to control the semiconductor device,
wherein the semiconductor device comprises:
a source structure;
a stack structure comprising interlayer insulating layers and gate electrodes stacked in a first direction perpendicular to an upper surface of the source structure, the stack structure comprising a channel hole penetrating the interlayer insulating layers and the gate electrodes in the first direction;
a filling insulating layer in a center of the channel hole;
a channel layer on an external side surface of the filling insulating layer;
a tunneling layer on an external side surface of the channel layer;
a charge trapping layer on the tunneling layer;
an antiferroelectric layer on the charge trapping layer, the antiferroelectric layer configured to have spontaneous polarization when a voltage is applied; and
a crystal seed layer on one side surface of the antiferroelectric layer, and
wherein the antiferroelectric layer has a tetragonal crystal structure.
